(19) United States
(12) Patent Application Publication
(10) Pub. No.: US 2017/0025560 A1
(43) Pub. Date: Jan. 26, 2017

(54) Solar cell module and method for manufacturing such a module

(71) Applicant: Stichting Energieonderzoek Centrum Nederland, Petten (NL)

(72) Inventors: Jacques Anna Josephus Peters, Petten (NL); Bas Bernardus van Aken, Petten (NL); Evert Eugène Bende, Petten (NL); Ian John Bennett, Petten (NL); Maarten de Bruijne, Petten (NL); Johannes Adrianus Maria van Roosmalen, Petten (NL)

(73) Assignee: Stichting Energieonderzoek Centrum Nederland, Petten (NL)

(21) Appl. No.: 15/300,792

(22) PCT Filed: Apr. 3, 2015
(86) PCT No.: PCT/EP2015/097009

§ 371 Date: Sep. 30, 2016

(30) Foreign Application Priority Data
Apr. 3, 2014 (NL) 2012563

(51) Int. Cl. H01L 31/05; H01L 31/0216; H01L 31/18; H01L 31/049

(52) U.S. Cl. CPC H01L 31/0516; H01L 31/049; H01L 31/02167; H01L 31/1864

(57) ABSTRACT

A method for manufacturing a solar cell module that includes a solar cell based on a semiconductor substrate with front and rear surfaces, includes—fabricating a solar cell from the substrate, and—depositing on at least the rear surface a coating layer.

The deposition step includes applying a coating powder on at least the rear surface, forming an adhered powder layer on said surface.

The method includes after the deposition step: performing a first annealing process on the solar cell module for transforming the adhered powder layer in a pre-annealed coating layer.

Further the method includes—creating open contacting areas on the solar cell by removal of the adhered powder layer at locations of contacting areas on the solar cell , wherein the removal precedes the first annealing process, or by masking contacting areas on the solar cell 1, wherein the masking precedes the deposition step.

### FIELD OF THE INVENTION

The invention relates to a solar cell module and to a method for manufacturing such a module. Additionally, the invention relates to a solar panel comprising such a solar cell module. Also, the present invention relates to a processing line and tools for manufacturing such solar cell modules and/or solar panel modules.

### BACKGROUND

Semiconductor based solar cell comprise a semiconductor substrate with a layer structure of a p-type doped layer and a n-type doped layer forming a p/n junction.

To reduce the amount of material in solar cells, there is a tendency to use thinner substrates. As a result the substrates become more fragile and more difficult to handle during the assembly into solar panels.

In solar panels consisting of solar cells with all contacts on the back side, contacts are typically connected to a conductor pattern on a back-sheet layer. In between the solar cell and the back-sheet layer an encapsulant layer is positioned with openings that correspond with the location of the contacts of the solar cells and of the corresponding contacting area on the conductor pattern. In the openings of the encapsulant layer a connecting material is applied for providing electrical contact between the solar cell contacts and the conductor pattern. The connecting material comprises typically an adhesive and a conductor based filler. The filler is typically a silver or silver alloy based powder. In order to reduce the amount of conductor based filler the encapsulant layer should be as thin as possible, provided that it retains its encapsulating and stress relieving properties.

In solar panels an perforated back-sheet is used. For big panels it is difficult to match the holes of the encapsulant sheet with the contact areas of the conductive patterned foil due to e.g. limited accuracy of the punching equipment that creates the holes in the encapsulant sheet and due to the limited dimensional stability of the encapsulant material.

In solar panels the conductive adhesive is stencil printed for the contacts of all cells. For big panels the accuracy of printing becomes insufficient which may lead to misaligned prints.

For module manufacturing machines are available that carry out the encapsulant perforation and the conductive adhesive printing on the conductive patterned back-sheet. This is typically done for modules with fixed predetermined sizes and the machines are not suited for production of modules with different variable sizes and shapes due to limitations in the accuracy of positioning of the tool(s).

Patent application US 2010/0116927 discloses a solar cell module comprising at least one photovoltaic element encapsulated between a front layer on its light receiving surface side and a back layer, said front layer comprising at least one layer comprising a tetrafluoroethylene (TFE) polymer.

Patent application US 2013/0087181 discloses a method for producing a photovoltaic module having backside-contacted semiconductor cells which have contact regions provided on a contact side, the method including providing a non-conducting foil-type substrate, placing the contact sides of the semiconductor cells on the substrate, implementing laser drilling which penetrates the substrate to produce openings in the contact regions of the contact sides of the semiconductor cells, depositing a contacting means on the substrate to fill the openings and to form a contacting layer extending on the substrate.

U.S. Pat. No. 8,440,903 discloses a a solar module formed using a powder coating and thermal treatment process. The solar module includes a substrate having a surface region and a photovoltaic material overlying the surface region. The solar module further includes a barrier material overlying the photovoltaic material. Moreover, the solar module includes a coating overlying the barrier material and enclosing the photovoltaic material to mechanically protect the photovoltaic material. In certain embodiments, photovoltaic material is a thin film photovoltaic cell and the coating is provided by a powder coating substantially free of bubbles formed by electrostatic spraying and cured with a thermal treatment process.

### SUMMARY OF THE INVENTION

It is an object of the invention to overcome the disadvantages from the prior art. The object is achieved by a method for manufacturing a solar cell module that comprises a solar cell based on a semiconductor substrate with a front surface for capturing radiation and a rear surface, the method comprising:
fabricating a solar cell from the semiconductor substrate;
depositing on at least one surface of the solar cell a coating layer, the deposition step comprising:
applying a coating powder on at least the rear surface, forming an adhered powder layer on said surface;
and after the deposition step:
performing a first annealing process on the solar cell for transforming the adhered powder layer in a pre-annealed coating layer so as to create a coated solar cell,
and wherein the method further comprises
either:
creating open contacting areas on the solar cell by removal of the adhered powder layer at locations of contacting areas on the solar cell , wherein the removal precedes the first annealing process, or
creating open contacting areas on the solar cell by masking contacting areas on the solar cell to prevent coverage by the adhered powder layer and to create open contacting areas on the solar cell, wherein the masking precedes the deposition step or deposition steps.

By the method a solar cell substrate is provided with a pre-annealed coating layer as a coating on at least one surface of the substrate. Due to the pre-annealing in the first annealing process, the coating powder particles are adhering to the substrate surface and are forming a percolated network with porosity or a dense layer. The porous or dense state of the pre-annealed coating layer is controlled by the conditions (e.g., duration and temperature) of the first annealing process.

The coating adds to the thickness of the substrate, thus providing strengthening of the substrate, in particular for “thin substrates” reducing the risk of fracture of the substrate during subsequent solar panel fabrication steps.

Additionally, the method provides that in case the coating material is a material suitable for encapsulation during solar panel production, the pre-annealed coating layer provides a precursor encapsulant layer for the solar panel lamination process.

During the stage that the powder adheres to the substrate, a selective removal of the powder or a selective masking at locations of the contacting areas on the solar cell provides that the contacting areas of the solar cell remain free from powder. The selective removal is possible for example by a vacuum nozzle that locally removes the powder. The vacuum nozzle may be positioned and controlled by a positioning device.

Alternatively, the contacting areas may also remain free from the powder by a masking preceding the powder coating step.

According to an aspect, the invention relates to a method as described above wherein the deposition step additionally comprises applying the coating powder on the front surface, forming an adhered powder layer on said surface.

The method may be used to provide a single sided or double sided coating of the substrate.

According to an aspect, the invention relates to a method as described above, further comprising removal of the adhered powder layer at locations of contacting areas on the solar cell to create open contacting areas on the solar cell.

According to an aspect, the invention relates to a method as described above, wherein the masking is performed by positioning the solar cell on a supporting tool, with each contacting area of the solar cell being covered by a protrusion of the supporting tool.

In this embodiment, the masking is provided by the supporting tool at the locations where the supporting tool contacts the solar cell's surface.

According to an aspect, the invention relates to a method as described above, wherein at least one protrusion of the supporting tool comprises a vacuum nozzle for holding the surface of the contacting area.

According to an aspect, the invention relates to a method as described above, wherein the first annealing process is conditioned to produce a porous layer as pre-annealed coating layer.

The porosity of the pre-annealed coating layer may be advantageous by providing channels for outgassing of the powder during the first annealing process.

According to an aspect, the invention relates to a method as described above, wherein the first annealing process is conditioned to produce a dense layer as pre-annealed coating layer.

A dense layer facilitates stenciling with a minimum amount of conductive adhesive. A thicker and porous layer may have some roughness that hampers the stencil process in a way that the stencil is not sufficiently flat on the rough and still thick porous layer. As a result, the distance from the openings in the stencil to the contacting area may be too high. The conductive adhesive dot would become relatively big and contain more material than needed.

According to an aspect, the invention relates to a method as described above, wherein the first annealing process is performed in a vacuum.

According to an aspect, the invention relates to a method as described above, comprising that the solar cell module is arranged between support layers, preceding the first annealing process, and the first annealing process is performed while the solar cell module is between the support layers.

According to an aspect, the invention relates to a method as described above, comprising pressing the support layers against the solar cell module.

According to an aspect, the invention relates to a method as described above, wherein the support layers are provided with a pattern of ribs. In this manner the pre-annealed coating layer is provided with a structure of channels that allows removal of gases during a later solar panel lamination process under vacuum.

According to an aspect, the invention relates to a method as described above, further comprising: applying a contacting material in the open contacting areas of the solar cell, by either a dispensing, jetting or a screen printing technique.

The amount of contacting material that needs to be applied in the openings of the pre-annealed coating layer reduces proportionately with the reduced thickness of the pre-annealed coating layer, which may save on the amount of contacting material needed and its costs.

According to an aspect, the invention relates to a method as described above, further comprising for the formation of a solar panel stack:
providing a panel module transparent cover layer:
arranging at least one solar cell on the panel module transparent cover layer, such that the contacting surface of the solar cell is facing away from the panel module transparent cover layer;
arranging a back-sheet layer on the at least one coated solar cell, the back-sheet layer arranged with a conductive layer pattern with contacting areas corresponding with the contacting areas of the solar cell;
exposing the solar panel stack to elevated temperature and pressure in a second annealing process, such that between the solar cell and the back-sheet layer the coating layer, as pre-annealed in the first annealing process, melts.

The coating layer as pre-annealed in the first annealing process is provided as encapsulant layer during the solar panel lamination process.

According to an aspect, the invention relates to a method as described above, further comprising for the formation of a solar panel stack: providing a panel module transparent cover layer:
arranging at least one solar cell on the panel module transparent cover layer, such that the contacting surface of the solar cell is facing away from the panel module transparent cover layer;
providing a back-sheet layer arranged with a conductive layer pattern with conductive layer contacting areas corresponding with the contacting areas of the solar cell; arranging contacting material on the conductive layer pattern contacting areas;
arranging the back-sheet layer on the at least one coated solar cell with the conductive layer pattern contacting areas corresponding with the contacting areas of the solar cell;
exposing the solar panel stack to elevated temperature and pressure in a second annealing process, such that between the solar cell and the back-sheet layer melts the coating layer pre-annealed in the first annealing process.

According to an aspect, the invention relates to a method as described above, wherein the coated solar cell comprises a second pre-annealed coating layer facing towards the panel module transparent cover layer, the second pre-annealed coating layer being melted during said elevated temperature and pressure exposure.

If the solar cell has been powder coated on both rear and front surfaces, the second pre-annealed coating layer is provided as encapsulant layer between the substrate and the panel module transparent cover layer.

Also, the porosity of the pre-annealed coating layer(s) may be advantageous during manufacturing of a solar panel stack in which solar cells provided with one or more porous pre-annealed coating layers are laminated. During this lamination process the porosity can provide flow paths in the pre-annealed coating layer for gas that allow an improved outgassing of gases located between the solar cell(s) and the back-sheet layer and/or the adjacent cover layer. In this manner the time required for degassing or outgassing may be reduced. Also, inclusion of gas within the solar panel stack can be prevented.

According to an aspect, the invention relates to a method as described above, comprising:—creating on a surface of the panel module transparent cover layer an adhered powder layer on said surface by using a powder coating technique,—exposing the panel module transparent cover layer to a panel module transparent cover annealing process so as to create a pre-annealed coating layer on the panel module transparent cover layer, and wherein the arrangement of the panel module transparent cover layer over the at least one coated solar cell comprises arranging the pre-annealed coating layer of the panel module transparent cover between the solar cell surface and the panel module transparent cover layer; the pre-annealed coating layer of the panel module transparent cover being melted during said elevated temperature and pressure exposure.

The panel module transparent cover layer may be provided with a powder coated layer as a precursor for an encapsulant layer between the substrate and the panel module transparent cover layer.

According to an aspect, the invention relates to a method as described above, wherein the coating powder is applied by electrostatic spraying.

According to an aspect, the invention relates to a method as described above, wherein the coating powder is applied by an electrostatic printing process or laser printing process.

By printing the powder on the substrate the pre-annealed coating layer can be transferred to the substrate including a pattern of openings over the contacting areas of the solar cell.

According to an aspect, the invention relates to a method as described above, wherein at least the pre-annealed coating layer between the at least one solar cell and the back-sheet layer has a thickness of about 100 μm or less.

Advantageously, the powder coating method allows to create coating layers that are relatively thin, which reduces the overall weight of the solar panel to be produced.

According to an aspect, the invention relates to a method as described above, after the exposure to elevated temperature and pressure the contacting material in the contacting areas has a thickness of about 100 μm or less.

Additionally, the amount of contacting material that needs to be applied in the openings of the pre-annealed coating layer reduces proportionately with the reduced thickness of the pre-annealed coating layer, which may save on the amount of contacting material needed and its costs.

According to an aspect, the invention relates to a method as described above, wherein the support layer or support layers consist of a Teflon or a Teflon-compound material.

Such a material facilitates easy release of the pre-annealed coating layer from the support layer(s).

According to an aspect, the invention relates to a method as described above, wherein the deposition step is performed using an electrical potential between the powder and the solar cell, and the electrical potential is created by electrostatic charging of the powder.

Advantageously, the electrical potential causes the powder to become charged, in a manner that the powder can be distributed over the surface of the substrate and adheres to the surface of the substrate.

The electrostatic charging can be done for example by an electrostatic spraying nozzle.

The present invention also relates to a solar cell module comprising a solar cell based on a semiconductor substrate with a rear and front surface, and at least one coating layer, wherein the at least one coating layer is a pre-annealed coating layer, and covers at least one of the rear and front surface.

The present invention provides a semi-finished solar cell product that by the coating layer is strengthened against fracture during subsequent processing steps to form a solar panel.

According to an aspect, the invention relates to a solar cell module as described above, wherein the coating layer consists of thermoplastic material.

The thermoplastic material allows to use the coating layer as encapsulant layer during a subsequent solar panel lamination process

According to an aspect, the invention relates to a solar cell module as described above, wherein the coating layer covers the rear surface and the front surface.

According to an aspect, the invention relates to a solar cell module as described above, wherein the coating layer comprises a free-standing extended portion extending perpendicular to the rear surface and to the front surface, around the circumference of the solar cell substrate.

In this manner an edge of thermoplastic material is provided around the solar cell substrate, which facilitates the handling of the solar cell module.

According to an aspect, the invention relates to a solar cell module as described above wherein the at least one coating layer has a thickness of 100 μm or less.

According to an aspect, the invention relates to a solar cell module as described above, wherein the at least one coating layer comprises openings at locations corresponding to locations of contacting areas on the solar cell.

Moreover, the present invention relates to a solar panel comprising a panel module transparent cover layer, at least one solar cell, and a back-sheet layer, wherein a first encapsulant layer is arranged between the back-sheet layer and the at least one solar cell, and a second encapsulant layer is arranged between the panel module transparent cover layer and the at least one solar cell; the first encapsulant layer being arranged with openings at locations corresponding to locations of contacting areas on the solar cell; contacting material being arranged in the openings between each contacting area of the at least one solar cell and a corresponding contacting area on the back-sheet layer, wherein at least the first encapsulant layer and the contacting material have a thickness of 100 μm or less.

Furthermore the present invention relates to a solar cell or solar panel processing line comprising a first station for powder coating a solar cell, and a second station for annealing the powder coated solar cell to create a coated solar cell with a pre-annealed coating layer on at least one surface of the solar cell.

According to an aspect, the invention relates to a processing line as described above, further comprising a third station for selectively removing coating powder from the powder coated solar cell wherein the third station is arranged intermediate the first station and the second station such that in use the solar cell passes the third station before reaching the second station.

According to an aspect, the invention relates to a processing line as described above, wherein the first station comprises a supporting tool comprising a plurality of pillars and a carrier, the pillars extending from the carrier and being positioned at locations corresponding to areas of the solar cell that are to be masked during the deposition of the powder coating on the solar cell.

According to an aspect, the invention relates to a processing line as described above, further comprising wherein the second station comprises a belt furnace, continuous support belts, and a driving mechanism for the support belts; the support belts being arranged in opposing positions for clamping a solar cell module during passage through the belt furnace.

Advantageous embodiments are further defined by the dependent claims.

### BRIEF DESCRIPTION OF DRAWINGS

The invention will be explained in more detail below with reference to drawings in which illustrative embodiments of the invention are shown.

FIG. 1 shows a cross-section of a solar cell module according to a manufacturing step according to an embodiment of the invention;

FIG. 2a, 2b show a cross-section of the solar cell module during subsequent manufacturing steps;

FIG. 3 shows a cross-section of the solar cell module during a further manufacturing step according to an embodiment of the invention;

FIG. 4 shows a cross-section of the solar cell module after a next manufacturing step;

FIG. 5 shows a cross-section of a solar panel module in accordance with an embodiment of the invention;

FIG. 6 shows a manufacturing step of a solar cell module according to an embodiment of the invention;

FIG. 7 shows a cross-section of a solar cell module after the step shown in FIG. 6;

FIG. 8 shows a top view of the solar cell module of FIG. 7;

FIG. 9 shows a top view of an arrangement of solar cell modules of FIG. 8;

FIG. 10 shows a cross-section of a solar cell module and a panel module transparent cover layer in accordance with an embodiment of the invention;

FIG. 11 shows a cross-section of a solar cell module during a manufacturing step in accordance with an embodiment of the invention;

FIG. 12 shows a schematic cross-section of a manufacturing step according to an embodiment of the invention.

### DETAILED DESCRIPTION OF EMBODIMENTS

The present invention relates to a method for manufacturing a solar cell module that is based on a semiconductor substrate, for example a solar cell made of a silicon substrate. The solar cell is typically a back contact type solar cell, such as MWT (metal wrap through), EWT (emitter wrap through), HIT (Heterojunction with thin intrinsic layer), IBC (interdigitated back contact). It is however conceivable that in some embodiments the invention also encompasses other solar cell types with front and back contacts.

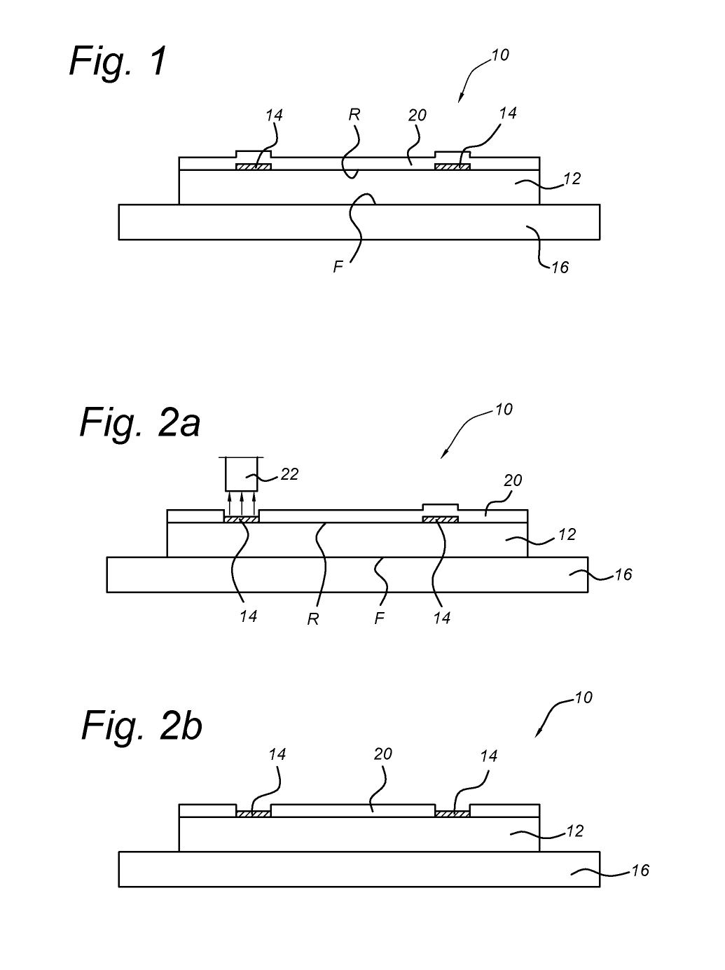

FIG. 1 shows a cross-section of a solar cell module 10 according to a manufacturing step according to an embodiment of the invention.

The solar cell module 10 comprises a solar cell 12 based on a semiconductor substrate as explained above. The solar cell 12 has a front surface F and a rear surface R. In this embodiment the contacting areas 14 of the solar cell are arranged at the rear surface R.

During this manufacturing step the solar cell 12 is positioned on a support layer 16.

The rear surface R and the contacting areas 14 are covered by an adhered powder coating layer 20. The adhered powder coating layer 20 has been deposited by exposing the rear surface R (and contacting areas) to particles of a powder under an electric potential between the particles and the rear surface.

In an embodiment, the electrical potential is created by electrostatic charging of the powder.

In an alternative embodiment, the coating powder is applied by electrostatic spraying. In yet a further alternative wherein the coating powder is applied by an electrostatic printing process (e.g., a toner and drum based laser printing process).

In a preferred embodiment, the powder coating consists of thermoplastic material suitable as encapsulant material for a solar panel stack.

FIG. 2a, 2b show a cross-section of the solar cell module during subsequent manufacturing steps.

In FIG. 2a, the solar cell module is shown with a nozzle 22 at some distance from the adhered powder coating layer 20. The nozzle is arranged to selectively remove coating powder at predetermined locations such as the contacting areas 14 from the adhered powder coating layer 20. In this manner, open contacting areas 14 substantially free from the coating powder are created.

In an alternative embodiment, the removal step is replaced by a masking step which prevents coating powder to accumulate at positions on the rear surface that are masked. Masking is done preceding the deposition step.

In a further embodiment, the masking is performed by positioning the solar cell on a supporting tool (not shown), with each contacting area (or selectively open area) of the solar cell being covered by a pillar of the supporting tool.

FIG. 2b shows a cross-section of the solar cell module after the removal step with the open contacting areas 14. In the embodiment with a masking step, FIG. 2b shows the solar cell module after removal of the masking tool.

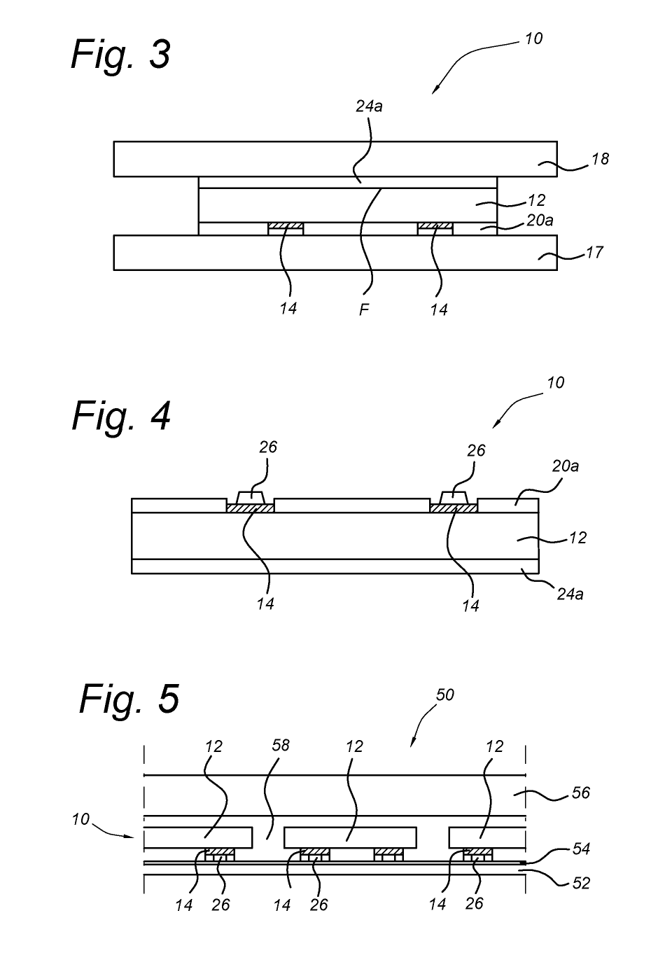

FIG. 3 shows a cross-section of the solar cell module during a further manufacturing step according to an embodiment of the invention.

The adhered powder coating layer on the rear surface R is covered by a second support layer 17, and the front surface F is now exposed to powder particles to form an adhered powder coating layer 24 on the front surface F in a similar manner as the powder coating layer 20 on the rear surface R. Next, the adhered powder coating layer 24 is covered by a support layer 18.

In a subsequent step, the solar cell 12 stacked between the adhered powder coating layers 20, 24 is exposed to elevated temperature to transform the adhered powder coating layers in pre-annealed coating layers 20a, 24a (solidification step).

The annealing may be done under vacuum conditions.

The conditions of the annealing and the optional vacuum are configured to either partially or fully melt the powder coating layers to create a pre-annealed coating in a range of a porous pre-annealed coating layer (in a pre-tacking step) to a dense pre-annealed coating layer (in a pre-laminating step), respectively.

According to an embodiment, the thickness of the pre-annealed coating layers 20a, 24a is 100 μm or less. The thickness can be controlled by parameters of the powder coating process and powder parameters such as average grain size and size distribution.

As a result of the solidification step, the powder coating layers become less brittle and obtain a relatively improved adhesion to the rear and front surfaces of the solar cell 12.

During the solidification step, the support layers 17, 18 remain positioned to clamp and support the solar cell module 10 (i.e., the solar cell 12 and powder coating layers 20, 24).

In an embodiment, the support layers consist of Teflon (PTFE) or a Teflon compound, which have excellent lift-off properties for most thermoplastic material and thus can be reused.

In an embodiment, the surface of one or both of the support layers is provided with a rib pattern, which is transferred into the respective pre-annealed coating layer or layers to create a patterned surface profile on the pre-annealed coating layer(s).

The skilled in the art will appreciate that the solidification step is carried out in such conditions that prevent the melted powder coating layer 20 to cover the openings at the contacting areas. After the solidification step the openings at the contacting areas remain open.

FIG. 4 shows a cross-section of the solar cell module after a next manufacturing step.

After the solidification step, the support layers 17, 18 have been removed. Next, contacting material 26 is applied at the contacting areas 14.

The contacting material 26 may be dispensed at the location of the contacting areas 14 in the case the pre-annealed coating layers 20a, 24a are porous i.e., formed by the pre-tacking step. In case the pre-annealed coating layers have been created in the pre-laminating step, the contacting material may also be screen printed, stencil printed or jetted.

The application of the contacting material 26 on the contacting areas of the solar cell module has an advantage that in comparison to application of the contacting material on the back-sheet layer, the application is done over a relatively small area which can be done more accurately without requiring tools that are accurate over substantially the size of back-sheet layer. Moreover, in case of a misaligned print on a solar cell module, only the solar cell module needs replacement while a misaligned print on back-sheet would involve removal of the complete back-sheet.

FIG. 5 shows a solar panel module 50 in accordance with an embodiment of the invention.

The solar panel module 50 comprises a stack of a back-sheet layer 52, a patterned conductive layer 54, a plurality of solar cell modules 10 and a panel module transparent cover layer 56.

The patterned conductive layer 54 is arranged on the back-sheet layer facing towards the solar cell modules 10. The contacting areas 14 on the rear surface R of the solar cells 12 are directed towards the patterned conductive layer 54. On top of the solar cells the panel module transparent cover layer (a glass layer or transparent foil layer) 56 is arranged.

The solar panel module is manufactured in bottom up direction by providing the back-sheet layer plus patterned conductive layer, arranging a plurality of solar cell modules 10 on the pattern conductive layer such that the locations of the contacting material on the solar cell module are positioned at associated locations on the patterned conductive layer. On top of the solar cell modules 10 the panel module transparent cover layer is arranged.

According to the invention, the stack does not contain separate encapsulant layers, since the solar cell modules comprise pre-annealed coating layers that provide material for encapsulation. Thus, the invention simplifies the stacking sequence since there is no need for arranging encapsulant layers in the solar panel stack that according to prior art processes would require accurate matching of positions with the patterned conductive layer. Since this step is omitted the stacking requires less time.

After creating the stack, a lamination process is carried out to fuse the stack, by melting of the material of the pre-annealed coating layers 20a, 24a in a second annealing process. After lamination the solar panel module is cooled down. The pre-annealed coating layers 20a and 24a of the solar cell modules have fused and formed encapsulation 58 between the panel module transparent cover layer and the solar cells, between the solar cells and the back-sheet layer and in between adjacent solar cells.

If the pre-annealed coating layer(s) 20a, 24a was in a porous state, the porosity allows that application of a vacuum during the lamination process is enhanced, since outgassing through the porous layer improves the degassing step during the lamination process. The porosity in the pre-annealed coating layer comprises channels of interconnected voids that provide flow paths for gas molecules through the pre-annealed coating layer.

It is noted that if alternatively or additionally the pre-annealed coating layer(s) 20a, 24a was provided with a rib pattern, the rib pattern allows that application of a vacuum during the lamination process is facilitated, by providing channels for degassing the solar panel stack.

As a result of the use of the pre-annealed coating layers on the solar cells, the thickness of the encapsulation 58 is determined by the initial thickness of the pre-annealed coating layers. The thickness of the encapsulation between solar cell and panel module transparent cover layer or between solar cell and back-sheet layer can be 100 μm or less which is relatively thin in comparison with prior art encapsulations in solar panels. The relatively thin encapsulation allows that the required amount of contacting material between a solar cell contact and a contact of the patterned conductive layer is significantly reduced in comparison with the prior art.

The skilled in the art will appreciate that the creating of the solar panel stack may be done in reversed order, i.e. top down by providing a panel module transparent cover layer; arranging the solar cell modules on the panel module transparent cover layer, the rear surface of the solar cells facing away from the panel module transparent cover layer; and subsequently arranging the patterned conductive layer and back-sheet over the solar cell modules.

It will be appreciated that additional coating powder may be added between adjacent solar cell modules during or subsequent the step of arranging the solar cell modules in the solar panel stack. If needed, the additional coating powder will provide additional encapsulant material to fill gaps between adjacent solar cell modules.

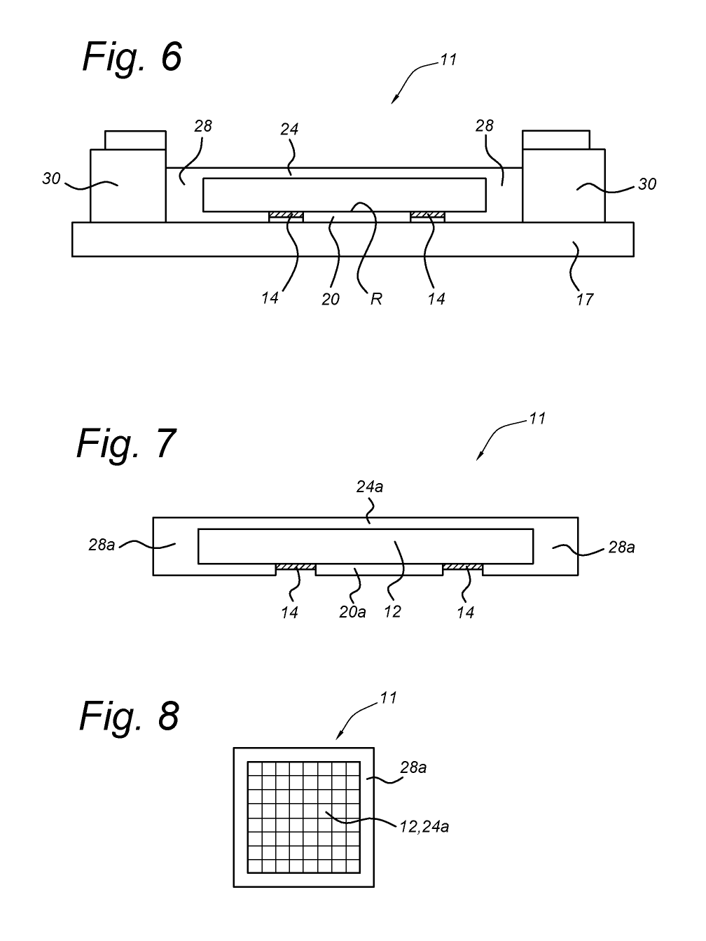

FIG. 6 shows a manufacturing step of a solar cell module 11 according to an embodiment of the invention. In this embodiment, after forming the powder coating layer 20 on the rear surface R and after opening the contacting areas at the rear surface, the solar cell module 11 is positioned on the support layer 17, the rear surface facing towards the support layer and the front surface F still free of a powder coating layer facing away.

Around the solar cell module 11, masking elements 30 are positioned that create circumferential edge around the solar cell module 10.

Subsequently, a powder coating deposition step is carried out to cover the front surface F with a powder coating layer 24. Additionally, a powder coated layer portion 28 that extends around the circumference of the solar cell 12 is created.

FIG. 7 shows a cross-section of a solar cell module 11 of FIG. 5 after a solidification step. The extending powder coating layer portions 28 have been transformed into pre-annealed extensions 28a during the solidification step.

FIG. 8 shows a top view of the solar cell module 11 of FIG. 6 with a central portion where the solar cell 12 is covered by the pre-annealed coating layers 20a, 24a, and a peripheral portion consisting of pre-annealed coating layer material 28a.

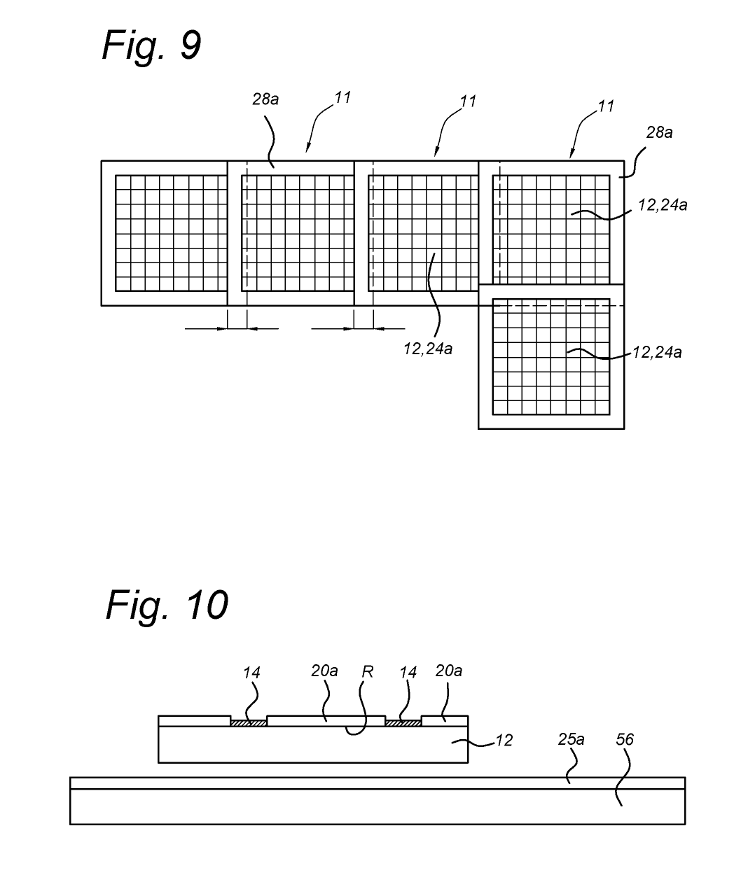

FIG. 9 shows a top view of an arrangement of solar cell modules 11 of FIG. 7 during construction of a solar panel.

A plurality of solar cell modules 11 with extended pre-annealed coating layers 28a is arranged adjacent to each other with their respective extended pre-annealed coating layers 28a overlapping each other.

In an embodiment, the solar cell modules 11 are stacked like roof-tiles.

The use of solar cell modules 11 with extended pre-annealed coating layers 28a in a solar panel has an advantage since the extended pre-annealed coating layers 28a additional material for the encapsulation 58 of the solar panel can serve as additional feed for encapsulating material and may remove the need for adding separate encapsulation material during the creation of the solar panel stack.

FIG. 10 shows a cross-section of a solar cell module and a panel module transparent cover layer in accordance with an embodiment of the invention.

In an alternative embodiment, the solar cell modules are provided with a pre-annealed coating layer 20a on only the rear surface R of the solar cell 12, while the front surface are substantially free from a powder coating layer. According to the invention, the panel module transparent cover layer 56 is provided with a pre-annealed coating layer 25a, created by a deposition process with powder coating followed by an annealing step (either pre-tacking or pre-laminating), in a similar manner as for the solar cell module.

The solar panel stack is created by arranging the front surface of the solar cell modules on the pre-annealed coating layer 25a of the panel module transparent cover layer, subsequently arranging the patterned conductive layer and back-sheet layer over the solar cell modules, and then performing a lamination process on the solar panel stack.

The pre-annealed coating layer 25a may be arranged to have a surplus thickness which during the panel module lamination step can provides as feed material to fill gaps between adjacent solar cell modules with encapsulant material.

Alternatively, instead of a powder coated pre-annealed coating layer 25a, an encapsulant layer may be arranged between the panel module transparent cover layer and the solar cell modules.

Also, as alternative, the front surface of the solar cell modules are covered by a pre-annealed coating layer while at the side of the rear surface a patterned encapsulant layer is provided between the rear surface of the solar cells and the conductive layer pattern on the back-sheet layer.

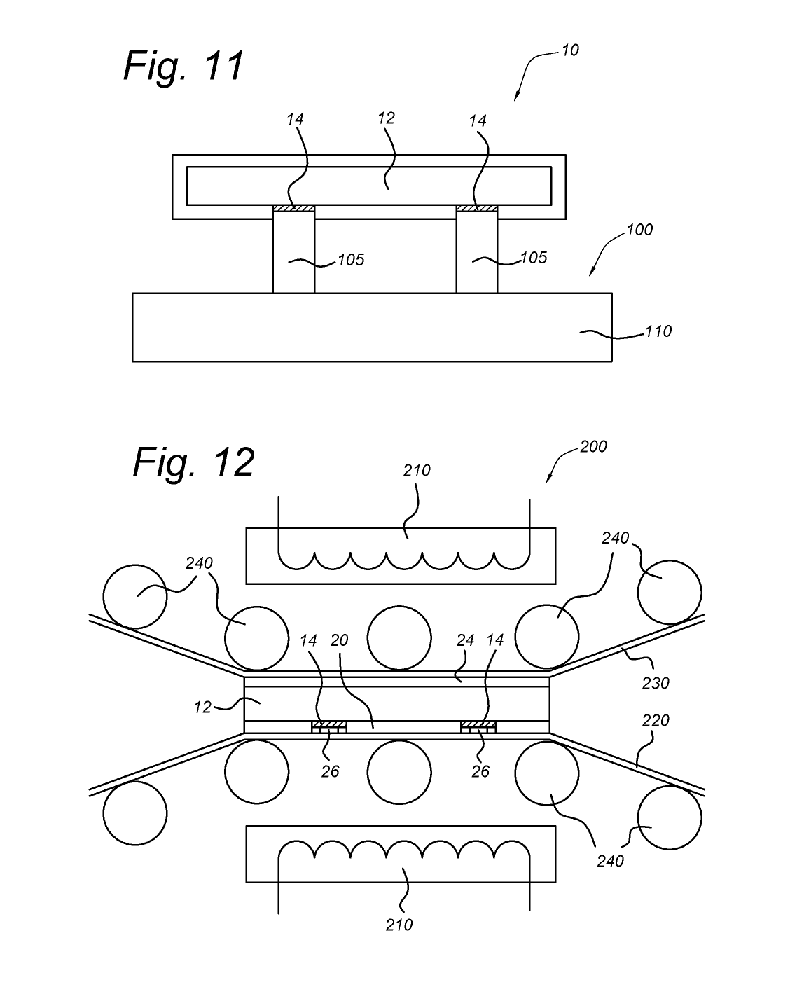

FIG. 11 shows a cross-section of a solar cell module during a manufacturing step in accordance with an embodiment of the invention.

In this embodiment, the solar cell is mounted on a supporting tool 100 comprising a plurality of pillars 105 and a carrier 110. The pillars 105 extend from a carrier 110 and are positioned at locations corresponding to areas of the solar cell that are to be masked during the deposition of the powder coating on the solar cell.

Preceding the deposition process the solar cell 12 is mounted on the supporting tool 100, and the areas to be masked aligned with the position of the pillars 105. One or more of the pillars can be embodied as a vacuum nozzle to clamp the solar cell on the supporting tool 100.

The pillars 105 extend from the carrier 110 to have space between the solar cell 12 and the supporting tool.

Next, a deposition process is performed to deposit coating powder on the solar cell to create an adhered coating layer. Since the solar cell is only covered at the positions to be masked, the deposition process can provide an all-sided deposition of coating powder in a single deposition process.

In an embodiment, the pillars 105, and optionally the carrier 110, consist of a Teflon or Teflon based compound.

After the deposition process the solar cell 12 with the adhered coating layer 21 is arranged on the support layers and processed further as described above.

FIG. 12 shows a schematic cross-section of a manufacturing tool 200 according to an embodiment of the invention.

The manufacturing tool 200 relates to a pre-tacking or pre-laminating furnace for creating solar cell modules with pre-annealed coating layers 20a, 24a.

The manufacturing tool 200 comprises a belt furnace 210, continuous support belts 220, 230, and a driving mechanism 240 for the support belts.

The support belts are arranged in opposing positions for clamping a solar cell module in between them.

The support belts pass through the belt furnace, in a manner that the adhered coating layers 20, 24 and extended coating layers 28, if present, are transformed in pre-annealed coating layers, in either a pre-tacking or pre-laminating mode.

The manufacturing tool may be equipped with a powder coating station (not shown) within the path of the support belts.

In an embodiment, the manufacturing tool 200 is part of a solar cell or solar panel processing line with a first station for powder coating a solar cell, and a second station for annealing the powder coated solar cell to create a coated solar cell with a pre-annealed coating layer on at least one surface of the solar cell.

According to an embodiment, the solar cell or solar panel processing line is equipped with a third station for selectively removing coating powder from the powder coated solar cell. The third station is arranged intermediate the first station and the second station such that in use the solar cell passes the third station before reaching the second station.

In an embodiment, the supporting tool as shown in FIG. 11 may be part of the first station of the solar cell or solar panel processing line.

The invention has been described with reference to some embodiments. Obvious modifications and alterations will occur to the skilled in the art upon reading and understanding the preceding detailed description. It is intended that the invention be construed as including all such modifications and alterations, the scope of the invention being limited only by the appended claims.

1. A method for manufacturing a solar cell module that comprises a solar cell based on a semiconductor substrate with a front surface for capturing radiation and a rear surface,
the method comprising:
fabricating a solar cell from the semiconductor substrate;
depositing on at least one surface of the solar cell a coating layer,
the deposition step comprising:
applying a coating powder on at least the rear surface, forming an adhered powder layer on said surface;
and after the deposition step:
performing a first annealing process on the solar cell for transforming the adhered powder layer in a pre-annealed coating layer so as to create a coated solar cell, and wherein the method further comprises
either:
creating open contacting areas on the solar cell by removal of the adhered powder layer at locations of contacting areas on the solar cell, wherein the removal precedes the first annealing process,
or
creating open contacting areas on the solar cell by masking contacting areas on the solar cell to prevent coverage by the adhered powder layer and to create open contacting areas on the solar cell, wherein the masking precedes the deposition step or deposition steps.

2. The method according to claim 1, wherein the open contacting areas on the solar cell are free from coating powder.

3. The method according to claim 1, wherein the deposition step additionally comprises applying the coating powder on the front surface, forming an adhered powder layer on said surface.

4. The method according to claim 1, wherein the masking is performed by positioning the solar cell on a clamping tool, with each contacting area of the solar cell being covered by a protrusion of the clamping tool.

5. The method according to claim 4, wherein at least one protrusion of the clamping tool comprises a vacuum nozzle for holding the surface of the contacting area.

6. The method according to claim 1, wherein the first annealing process is conditioned to produce a porous layer as pre-annealed coating layer.

7. The method according to claim 1, wherein the first annealing process is conditioned to produce a dense layer as pre-annealed coating layer.

8. The method according to claim 6, wherein the first annealing process is performed in a vacuum.

9. The method according to claim 6, comprising that the solar cell module is arranged between support layers, preceding the first annealing process, and the first annealing process is performed while the solar cell module is between the support layers.

10. The method according to claim 9, comprising pressing the support layers against the solar cell module.

11. The method according to claim 10, wherein the support layers are provided with a pattern of ribs.

12. The method according to claim 6, comprising the method comprises applying a contacting material in the open contacting areas of the solar cell, by either a dispensing, jetting or a screen printing technique.

13. The method according to claim 12, further comprising for the formation of a solar panel stack by:
providing a panel module transparent cover layer:
arranging at least one solar cell on the panel module transparent cover layer, such that the contacting surface of the solar cell is facing away from the panel module transparent cover layer;
arranging a back-sheet layer on the at least one coated solar cell, the back-sheet layer arranged with a conductive layer pattern with conductive layer pattern contacting areas location-wise corresponding with the contacting areas of the solar cell;
exposing the solar panel stack to elevated temperature and pressure in a second annealing process, such that between the solar cell and the back-sheet layer the coating layer as pre-annealed in the first annealing process, melts.

14. The method according to claim 6, further comprising for the formation of a solar panel stack:
providing a panel module transparent cover layer:arranging at least one solar cell on the panel module transparent cover layer, such that the contacting surface of the solar cell is facing away from the panel module transparent cover layer;
providing a back-sheet layer arranged with a conductive layer pattern with conductive layer contacting areas location-wise corresponding with the contacting areas of the solar cell;
arranging contacting material on the conductive layer pattern contacting areas;
arranging the back-sheet layer on the at least one coated solar cell with the conductive layer pattern contacting areas corresponding with the contacting areas of the solar cell;
exposing the solar panel stack to elevated temperature and pressure in a second annealing process, such that between the solar cell and the back-sheet layer the coating layer as pre-annealed in the first annealing process, melts.

15. The method according to claim 13, wherein the coated solar cell comprises a second pre-annealed coating layer facing towards the panel module transparent cover layer, the second pre-annealed coating layer being melted during said elevated temperature and pressure exposure in the second annealing process.

16. The method according to claim 13, comprising:
creating on a surface of the panel module transparent cover layer an adhered powder layer on said surface by using a powder coating technique,
exposing the panel module transparent cover layer to a panel module transparent cover annealing process so as to create a cover pre-annealed coating layer on the panel module transparent cover layer,
and wherein the arrangement of the panel module transparent cover layer over the at least one coated solar cell comprises arranging the pre-annealed coating layer between the solar cell surface and the panel module transparent cover layer;
the pre-annealed coating layer being melted during said elevated temperature and pressure exposure in the second annealing process.

17. The method according to claim 1 wherein the coating powder is applied by electrostatic spraying.

18. The method according to claim 1, wherein the coating powder is applied by an electrostatic printing process or laser printing process.

19. The method according to claim 1, wherein at least the pre-annealed coating layer between the at least one solar cell and the back-sheet layer has a thickness of about 100 μm or less.

20. The method according to claim 13, wherein after the exposure to elevated temperature and pressure the contacting material in the contacting areas has a thickness of about 100 μm or less.

21. The method according to claim 9, wherein the support layer or support layers consist of a Teflon or a Teflon-compound material.

22. The method according to claim 1, wherein the deposition step is performed using an electrical potential between the powder and the solar cell, and the electrical potential is created by electrostatic charging of the powder.

23. A solar cell module manufactured in accordance with claim 1, comprising a solar cell based on a semiconductor substrate with a rear and front surface, and at least one coating layer,
wherein the at least one coating layer is a pre-annealed powder coated layer which has been pre-annealed in a first annealing process and covers at least one of the rear and front surface.

24. The solar cell module according to claim 23, wherein the coating layer consists of thermoplastic material.

25. The solar cell module according to claim 23, wherein the coating layer covers the rear surface and the front surface.

26. The solar cell module according to claim 25, the coating layer comprises a free-standing extended portion extending substantially parallel to the rear surface and to the front surface, around the circumference of the solar cell substrate.

27. The solar cell module according to claim 23, wherein the at least one coating layer has a thickness of 100 μm or less.

28. The solar cell module according to claim 23, wherein the at least one coating layer comprises openings at locations corresponding to locations of contacting areas on the solar cell.

29. The solar cell module according to claim 23, wherein the coating layer is in either porous or dense state.

30. A solar panel comprising a panel module transparent cover layer, at least one solar cell, and a back-sheet layer, wherein
the solar cell is a coated solar cell manufactured according to claim 1 or a solar cell module according to claim 23;
a first encapsulant layer is arranged between the back-sheet layer and the at least one solar cell, and a second encapsulant layer is arranged between the panel module transparent cover layer and the at least one solar cell;
the first encapsulant layer being arranged with openings at locations corresponding to locations of contacting areas on the solar cell;
contacting pads being arranged in the openings between each contacting area of the at least one solar cell and a corresponding contacting area on the back-sheet layer,
wherein at least the first encapsulant layer and the contacting pads have a thickness of 100 μm or less.

31. A solar cell or solar panel processing line comprising a first station for powder coating a solar cell,
and a second station for annealing the powder coated solar cell to create a coated solar cell with a pre-annealed coating layer on at least one surface of the solar cell, and comprising a third station for selectively removing coating powder from the powder coated solar cell wherein the third station is arranged intermediate the first station and the second station such that in use the solar cell passes the third station before reaching the second station.

32. The solar cell or solar panel processing line according to claim 31, wherein the first station comprises a supporting tool comprising a plurality of pillars and a carrier, in which the pillars extend from the carrier, are arranged to support a solar cell and are positioned at locations corresponding to areas of the solar cell that are to be masked during the deposition of the powder coating on the solar cell.

33. The solar cell or solar panel processing line according to claim 31, wherein the second station comprises a belt furnace, continuous support belts, and a driving mechanism for the support belts; the support belts being arranged in opposing positions for clamping a solar cell module during passage of the solar cell through the belt furnace.
